(19) United States
(12) Patent Application Publication
(10) Pub. No.: US 2012/0013185 A1
(43) Pub. Date: Jan. 19, 2012

(54) FUEL CELL SYSTEM

(75) Inventor: Yasuhiko Ohashi, Toyota-shi (JP)

(73) Assignee: TOYOTA JIDOSHA KABUSHIKI KAISHA, Toyota-shi (JP)

(21) Appl. No.: 13/259,868

(22) PCT Filed: Jun. 3, 2009
(86) PCT No.: PCT/JP2009/060109

§ 371 Date: Sep. 23, 2011

(51) Int. Cl. B60L 11/18; H05K 7/04

(52) U.S. Cl. 307/10.1; 361/807

(57) ABSTRACT

The largest possible compartment space is secured in a fuel cell hybrid vehicle. A reactor unit, a voltage-increase control unit 61b and a condenser unit included in an FC converter are integrated so that they do not superpose on each other in the thickness directions of the respective rectangular parallelepiped shape. In other words, the FC converter is formed by integrating the reactor unit, the voltage-increase control unit and the condenser unit in a flat state. Such an FC converter is arranged on the upper, lower or rear side of the fuel cell.

### FIELD OF THE INVENTION

The invention relates to a fuel cell system.

### BACKGROUND OF THE INVENTION

In a fuel cell having a stack structure with a large number of unit cells stacked therein, voltages of the unit cells might vary between the unit cells due to the distributions of density, humidity and temperature of a fuel gas inside the stack. Thus, it is necessary to monitor the state of each unit cell in the fuel cell and to control a power generation current based on the state. Patent document 1 below discloses a fuel cell system which enhances the controllability in the control of a power generation current in accordance with the state of each unit cell in a fuel cell by integrating the fuel cell and a DC/DC converter which is a voltage converter.

### RELATED ART REFERENCE

Patent document 1: Japanese laid-open patent publication No. 2007-207582

### DISCLOSURE OF THE INVENTION

### Problem to be Solved by the Invention

A fuel cell vehicle having a fuel cell arranged under the floor of the vehicle requires that space for installing the fuel cell be provided while minimizing the sacrifice in compartment space. However, various constraints exist in providing the space for installing the fuel cell under the floor while securing enough compartment space and thus it is difficult to achieve such requirements. Accordingly, in a configuration where the fuel cell and a voltage converter are integrated and installed under the floor, it would be even more difficult to achieve the requirements.

The present invention has been made in order to solve the above problem in the related art, and it is an object of the present invention to provide a fuel cell system capable of securing the largest possible compartment space in an object in which the fuel cell system is to be installed.

### Means for Solving the Problem

In order to achieve the object above, provided according to the present invention is a fuel cell system which comprises: a fuel cell; and a voltage converter which increases an output voltage from the fuel cell and outputs the resulting output voltage to a power-consuming apparatus, wherein a reactor unit, a voltage-increase control unit and a condenser unit included in the voltage converter are integrated so that the reactor unit, the voltage-increase control unit and the condenser unit do not superpose on each other in respective thickness directions thereof.

Since the reactor unit, the voltage-increase control unit and the condenser unit included in the voltage converter can be integrated in a flat state, the thickness of the entire voltage converter can be minimized.

In the fuel cell system above, the voltage converter is arranged on an upper side of the fuel cell with respect to the fuel cell which has been arranged.

With such a configuration, the voltage converter can be arranged on the upper side of the fuel cell with the thickness of the voltage converter minimized, and the thickness of the fuel cell and voltage converter, when being integrated, can be minimized.

In the fuel cell system above, the voltage converter is arranged on a lower side of the fuel cell with respect to the fuel cell which has been arranged.

With such a configuration, the voltage converter can be arranged on the lower side of the fuel cell with the thickness of the voltage converter minimized, and the thickness of the fuel cell and voltage converter, when being integrated, can be minimized.

In the fuel cell system above, the voltage converter is arranged on a rear side of the fuel cell with respect to the fuel cell which has been arranged.

With such a configuration, the voltage converter can be arranged on the rear side of the fuel cell with the thickness of the voltage converter minimized, and the thickness of the fuel cell and voltage converter, when being integrated, can be minimized.

The fuel cell system above further comprises: a cooling-water circulation flow path which circulates and supplies cooling water to the fuel cell; and a cooling-water pump which causes the cooling water to circulate in the cooling-water circulation flow path, wherein the cooling-water pump is arranged on a front side of the fuel cell and the voltage converter with respect to the fuel cell and the voltage converter which have been arranged.

With such a configuration, the cooling-water pump can function as a buffer for buffering, when a vehicle crash from the front side occurs, an impact resulting from the crash, and thus the fuel cell and the voltage converter can be protected from the impact resulting from the vehicle crash.

The fuel cell system above further comprises an ion exchanger which removes impurities contained in the cooling water, wherein the ion exchanger is arranged on a front side of the fuel cell and the voltage converter with respect to the fuel cell and the voltage converter which have been arranged.

With such a configuration, the ion exchanger can function as a buffer for buffering, when a vehicle crash from the front side occurs, an impact resulting from the crash, and thus the fuel cell and the voltage converter can be protected from the impact resulting from the vehicle crash.

The fuel cell system above further comprises a protection member which protects the fuel cell, wherein a part of the protection member is arranged so as to cross with a joint portion formed on the fuel cell, as seen from a lateral side of the fuel cell and the voltage converter which have been arranged.

With such a configuration, the joint portion having a high strength and a part of the protection member can be arranged substantially in an X shape, the strength against an impact from a lateral side can be enhanced.

### Effect of the Invention

The present invention can secure the largest possible compartment space in an object in which the fuel cell system is to be installed.

### BRIEF DESCRIPTION OF THE DRAWINGS

FIG. 1 is a configuration diagram schematically showing a fuel cell system according to an embodiment.

FIG. 2 is a perspective view schematically showing the external view of a DC/DC converter.

FIG. 3 is a perspective view schematically showing the external view of the fuel cell system according to the embodiment.

FIG. 4 is a perspective view showing the external view of a protection frame.

FIG. 5 is a perspective view schematically showing the external view of a fuel cell system in a first modification.

FIG. 6 is a perspective view schematically showing the external view of a fuel cell system in a second modification.

### BEST MODE FOR CARRYING OUT THE INVENTION

A preferred embodiment of a fuel cell system according to the present invention will be described below with reference to the attached drawings. This embodiment will describe a configuration in which the fuel cell system according to the present invention is used as an in-vehicle power generation system in a fuel cell hybrid vehicle (FCHV).

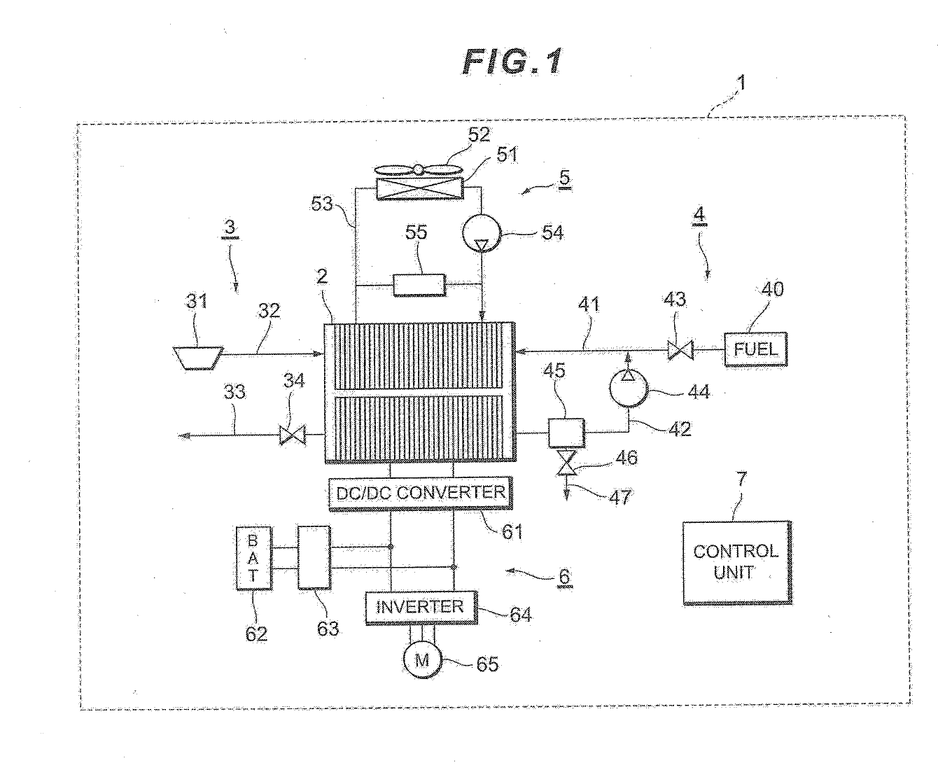

First, the configuration of the fuel cell system in this embodiment will be described with reference to FIG. 1. FIG. 1 is a configuration diagram schematically showing the fuel cell system in this embodiment.

As shown in FIG. 1, the fuel cell system 1 includes: a fuel cell 2 which is supplied with an oxidant gas and a fuel gas serving as reactant gases and which generates electric power through an electrochemical reaction; an oxidant gas pipe system 3 which supplies the air serving as the oxidant gas to the fuel cell 2; a fuel gas pipe system 4 which supplies hydrogen serving as the fuel gas to the fuel cell 2; a cooling system 5 which circulates and supplies cooling water to the fuel cell 2; a power system 6 which allows the system to be charged with electric power or to discharge the electric power; and a control unit 7 which centrally controls the entire system.

The fuel cell 2 is, for example, a polymer electrolyte fuel cell and has a stack structure having a large number of unit cells stacked therein. The unit cell has a cathode (air electrode) on one surface of an electrolyte constituted from an ion-exchange membrane and an anode (fuel electrode) on the other surface of the electrolyte, and the unit cell further has a pair of separators which sandwich the cathode and the anode from both sides thereof. In this configuration, the fuel gas is supplied to a fuel gas flow path in one separator while the oxidant gas is supplied to an oxidant gas flow path in the other separator, and electric power is generated through a chemical reaction between these reactant gasses.

The oxidant gas pipe system 3 includes: a compressor 31 which compresses the air introduced via a filter and sends out the compressed air as the oxidant gas; an oxidant gas supply flow path 32 for supplying the oxidant gas to the fuel cell 2; and an oxidant-off gas discharge flow path 33 for discharging an oxidant-off gas discharged from the fuel cell 2. The oxidant-off gas discharge flow path 33 is provided with a backpressure valve 34 for adjusting the pressure of the oxidant gas in the fuel cell 2.

The fuel gas pipe system 4 includes: a fuel tank 40 serving as a fuel supply source which stores hydrogen gas having a high pressure; a fuel gas supply flow path 41 for supplying the fuel gas in the fuel tank 40 to the fuel cell 2; and a fuel circulation flow path 42 for returning a fuel-off gas discharged from the fuel cell 2 to the fuel gas supply flow path 41. The fuel gas supply flow path 41 is provided with a pressure regulating valve 43 which regulates the pressure of the fuel gas to a preset secondary pressure. The fuel circulation flow path 42 is provided with a fuel pump 44 which compresses the fuel-off gas in the fuel circulation flow path 42 and sends the resulting gas toward the fuel gas supply flow path 41.

The fuel circulation flow path 42 is connected to a discharge flow path 47 via a gas-liquid separator 45 and an exhaust/drain valve 46. The gas-liquid separator 45 collects moisture from the fuel-off gas. The exhaust/drain valve 46 purges the moisture collected by the gas-liquid separator 45 and the fuel-off gas containing impurities in the fuel circulation flow path 42 in accordance with a command from the control unit 7. The fuel-off gas discharged from the exhaust/drain valve 46 is diluted by a diluter (not shown) and merges with the oxidant-off gas in the air discharge flow path 33.

The cooling system 5 includes: a radiator 51 and a radiator fan 52 which cool the cooling water; a cooling-water circulation flow path 53 which circulates and supplies the cooling water to the fuel cell 2 and the radiator 51; a cooling-water pump 54 which causes the cooling water to circulate in the cooling-water circulation flow path 53; and ion exchanger 55 which cleans the cooling water by removing ionic impurities contained in the cooling water.

The power system 6 includes a DC/DC converter 61 for the fuel cell (hereinafter referred to as the “FC converter”), a battery 62 being a secondary cell, a DC/DC converter 63 for the battery (hereinafter referred to as the “battery converter”), a traction inverter 64, a traction motor 65 (power consuming apparatus), and various types of auxiliary inverters (not shown).

The FC converter 61 is a direct-current voltage converter, which has the function of increasing a direct-current voltage output from the fuel cell 2 and outputting the resulting voltage to the traction inverter 64 on the side of the power consuming apparatus. The FC converter 61 controls an output voltage of the fuel cell 2.

The battery 62 has stacked battery cells and provides a certain high voltage as terminal voltage, the battery 62 being capable of being charged with surplus electric power of the fuel cell 2 and supplying electric power in an auxiliary manner under the control of a battery computer (not shown).

The battery converter 63 is a direct-current voltage converter, which has: the function of increasing a direct-current voltage output from the battery 62 and outputting the resulting voltage to the traction inverter 64; and the function of decreasing a direct-current voltage output from the fuel cell 2 or the traction motor 65 and outputting the resulting voltage to the battery 62. Due to such functions of the battery converter 63, the battery 62 can be charged and discharged.

The traction inverter 64 converts a direct current to a three-phase alternating current, and supplies the three-phase alternating current to the traction motor 65. The traction motor 65 is, for example, a three-phase alternating current motor, which serves as a main power source for, for example, a fuel cell hybrid vehicle equipped with the fuel cell system 1. The auxiliary inverters are motor control units which control the drive of respective motors, the auxiliary inverters each converting a direct current to a three-phase alternating current and supplying the three-phase alternating current to each motor.

The control unit 7 detects the amount of operation of an acceleration member (e.g., an accelerator) provided in the fuel cell hybrid vehicle, receives control information such as an acceleration request value (e.g., the amount of power generation required by power-consuming apparatuses such as the traction motor 65), and controls the operation of various apparatuses in the system. Examples of the power-consuming apparatuses may include, in addition to the traction motor 65, auxiliary apparatuses required for operating the fuel cell 2 (e.g., motors for the compressor 31, the fuel pump 44, the cooling-water pump 54 and the radiator fan 52); actuators used in various apparatuses relevant to the travel of the vehicle (e.g., a speed change gear, a wheel control apparatus, a steering gear and a suspension); and an air-conditioning apparatus (air conditioner), lighting equipment, audio system, etc. which are provided in a passenger compartment.

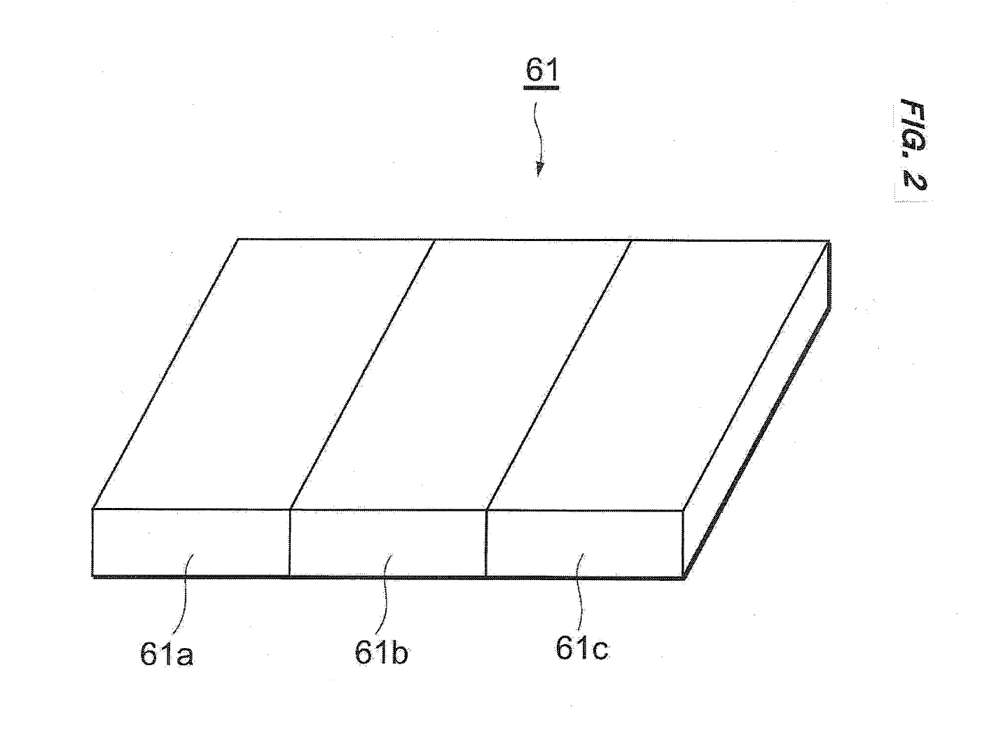

FIG. 2 is a perspective view schematically showing the external view of the FC converter 61. As shown in FIG. 2, the FC converter 61 has a reactor unit 61a, a voltage-increase control unit 61b and a condenser unit 61c. The reactor unit 61a, the voltage-increase control unit 61b and the condenser unit 61c each have a substantially rectangular parallelepiped outer shape.

The reactor unit 61a, the voltage-increase control unit 61b and the condenser unit 61c are integrated so that they do not superpose on each other in the thickness direction of each rectangular parallelepiped shape. In other words, the FC converter 61 is formed by the reactor unit 61a, the voltage-increase control unit 61b and the condenser unit 61c which are integrated in a flat state. With such a structure, the thickness of the entire FC converter 61 can be minimized.

The reactor unit 61a includes a reactor. The voltage-increase control unit 61b includes, for example, a transistor and a diode, the voltage-increase control unit 61b constituting a so-called IPM (Intelligent Power Module). The condenser unit 61c includes a condenser.

The voltage-increase control unit 61b controls the transistor to be turned on or off in accordance with a control signal from the control unit 7, thereby increasing a direct-current voltage output from the fuel cell 2 using the reactor in the reactor unit 61a, and supplies the resulting direct-current voltage to the condenser unit 61c. The condenser in the condenser unit 61c smoothes the direct-current voltage supplied from the voltage-increase control unit 61b and supplies the resulting direct-current voltage to the traction inverter 64.

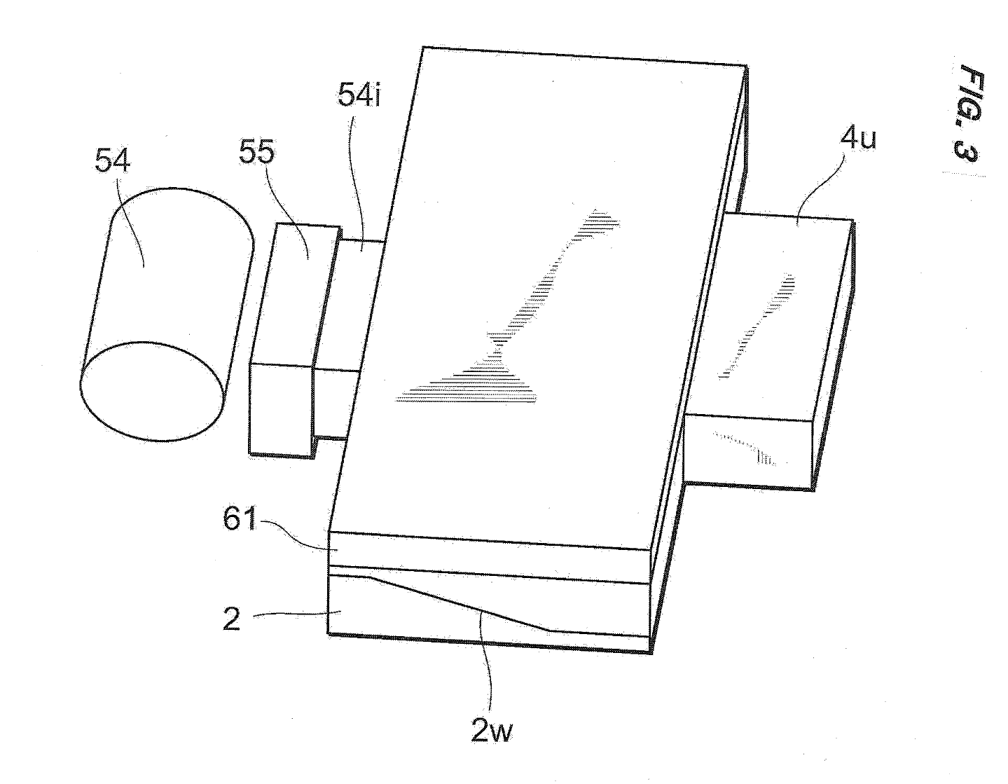

FIG. 3 shows a perspective view schematically showing the outer view of the fuel cell system which includes the FC converter shown in FIG. 2. The front side, rear side, upper side, lower side and lateral sides used in this specification can be determined based on the state in which the fuel cell 2 is being installed in the vehicle. For example, based on the state in which the fuel cell 2 is being installed in a vehicle, the direction in which the vehicle travels forward indicates the front side of the fuel cell 2, the direction in which the vehicle travels backward indicates the rear side of the fuel cell 2, the direction toward the ceiling of the vehicle indicates the upper side of the fuel cell 2, the direction toward a road surface indicates the lower side of the fuel cell 2, and lateral surfaces of the vehicle indicate the lateral sides of the fuel cell 2.

As shown in FIG. 3, the FC converter 61 is arranged on the upper side of the fuel cell 2 in the state in which the fuel cell is being installed in the vehicle. Disposed on the front side of the fuel cell 2 are, starting from the fuel cell 2 side, an inverter 54i for the cooling-water pump 54, the ion exchanger 55 and the cooling-water pump 54. Disposed on the rear side of the fuel cell 2 is a fuel-system non-power generating unit 4u. Examples of the fuel-system non-power generating unit 4u may include the gas-liquid separator 45, the diluter (not shown) and an injector (not shown). Note that the positions of the ion exchanger 55 and the cooling-water pump 54 may be exchanged with each other.

The FC converter 61 and the fuel cell 2 shown in FIG. 3 are arranged under a front seat of the vehicle. The inverter 54i for the cooling-water pump 54, the ion exchanger 55 and the cooling water pump 54 are arranged in a front floor part of a center tunnel of the vehicle. The fuel-system non-power generating unit 4u is arranged in a center floor part of the center tunnel of the vehicle.

In some related-art FC converters, a reactor unit, a voltage-increase control unit and a condenser unit are superposed in the thickness directions thereof (not in a flat state). If a fuel cell is further superposed on such a related-art FC converter and arranged under a front seat, the position of the front seat needs to be moved upward and thus the space of the passenger's compartment is sacrificed. In contrast, since the units constituting the FC converter 61 are integrated in a flat state in the present invention (see FIG. 2), the thickness of the FC converter 61 can be minimized, and thus the fuel cell 2 and the FC converter 61, even in the superposed state, can be arranged under a front seat of the vehicle without sacrificing the space of the passenger's compartment.

By arranging the inverter 54i for the cooling-water pump 54, the ion exchanger 55 and the cooling-water pump 54 on the front side of the fuel cell 2, when a vehicle crash from the front side occurs, these components can function as buffers which buffer an impact resulting from the crash. Accordingly, the fuel cell 2 and the FC converter 61 can be protected from an impact resulting from a vehicle crash from the front side.

Specifically, for example, in a vehicle having a front suspension member on the front side of the fuel cell system, when a vehicle crash from the front side occurs, the front suspension member moves backward, i.e., moves toward the fuel cell 2. In general, the front suspension member is mounted so as to be rotatable around its own axis, and no other component is arranged on the lower side (on the side of a road surface) of the front suspension member. Accordingly, if the front suspension member can be provided with a trigger which triggers the front suspension member to rotate downward around its own axis, the front suspension member can allow the force toward the fuel cell 2 to escape downward.

In this embodiment, the cooling water pump 54 is arranged at a position opposing the front suspension member as shown in FIG. 3. Since the cooling water pump 54 has a rounded surface, when the front suspension member moves toward the cooling water pump 54 from the front side, the cooling water pump 54 can serve as a trigger, for the front suspension member, which triggers the front suspension member to rotate downward around its own axis. Accordingly, by arranging the cooling water pump 54 on the front side of the fuel cell 2, the fuel cell 2 and the FC converter 61 can be prevented from being broken by the front suspension member moving toward them when a vehicle crash from the front side occurs. If the cooling-water pump does not have a rounded surface, the surface of the cooling-water pump may be provided with a guiding member which can guide the front suspension member obliquely downward.

The ion exchanger 55 is constituted from a filter made of resin and moisture, and thus when a vehicle crash occurs, the ion exchanger 55 would be crushed while absorbing an impact. Accordingly, by arranging the ion exchanger 55 on the front side of the fuel cell 2, the ion exchanger 55 can function as a buffer which absorbs an impact when a vehicle crash from the front side occurs. With such a configuration, the fuel cell 2 and the FC converter 61 can be protected from an impact resulting from a vehicle crash from the front side.

By arranging the inverter 54i for the cooling water pump 54, the ion exchanger 55 and the cooling water pump 54 on the front side of the fuel cell 2 and arranging the fuel-system non-power generating unit 4u on the rear side of the fuel cell 2, the number of components to be arranged under a front seat of the vehicle can be reduced to the maximum extent.

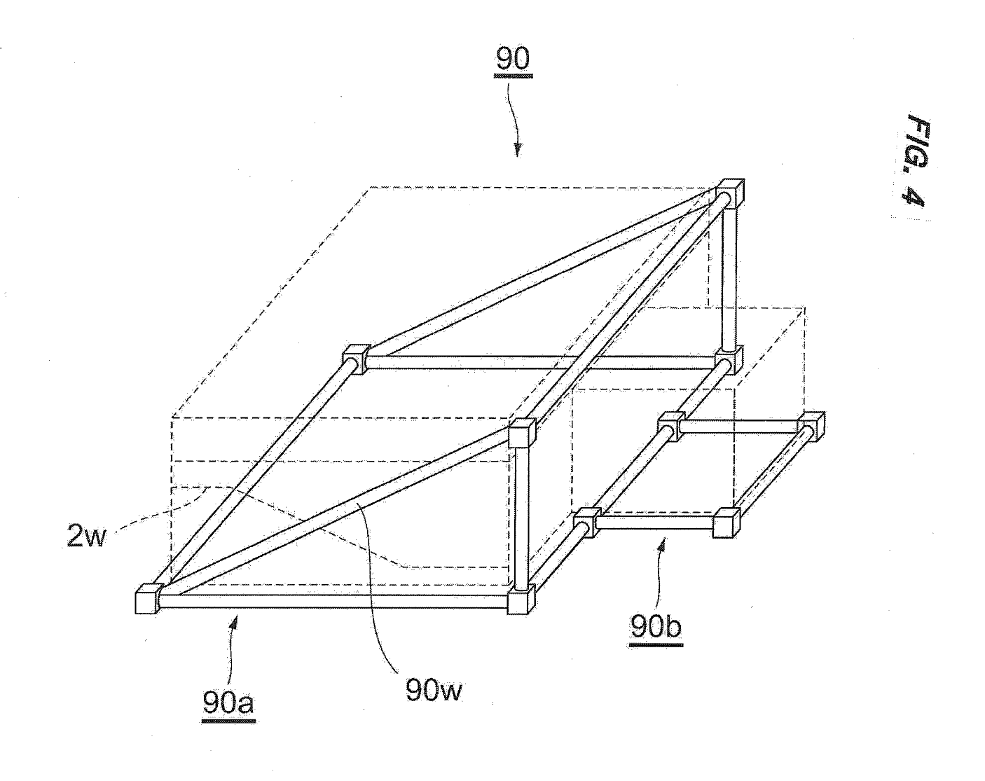

In addition, by providing a protection frame 90 (protection member) as shown in FIG. 4, the fuel cell 2 and the FC converter 61 can be protected from an impact resulting from a vehicle crash from a lateral side or an impact resulting from contact with a road surface. The protection frame 90 in FIG. 4 includes: a main frame unit 90a which protects the fuel cell 2 and the FC converter 61 from an impact resulting from a vehicle crash from a lateral side and an impact resulting from contact with a road surface; and a sub frame unit 90b which protects the fuel-system non-power generating unit 4u from an impact resulting from contact with a road surface.

A lateral-side frame 90w constituting a part of the main frame unit 90a is arranged at a position crossing a case joint portion 2w formed on the fuel cell 2, as seen from a lateral side of the fuel cell 2 which is being housed in the protection frame 90. The case joint portion 2w is formed so as to have a flange shape when an upper case and a lower case of the fuel cell 2 are joined together, and thus the case joint portion 2w has a high strength as compared to the other portions. Accordingly, by arranging the case joint portion 2w and the lateral-side frame 90w so as to cross each other substantially in an X shape, the strength against an impact from a lateral side can be enhanced. With such a configuration, when a vehicle crash from a lateral side occurs, the protection frame 90, the fuel cell 2 and the FC converter 61 can slide while maintaining their shapes, and the fuel cell 2 and the FC converter 61 can be thereby protected from an impact resulting from the vehicle crash from the lateral side.

In the fuel cell system according to the above embodiment, since the reactor unit 61a, the voltage-increase control unit 61b and the condenser unit 61c included in the FC converter 61 can be integrated in a flat state, the thickness of the entire FC converter 61 can be minimized. Also, since the FC converter 61 can be arranged on an upper side of the fuel cell 2 with the thickness of the FC converter 61 minimized, the thickness of the fuel cell 2 and the FC converter 61, when being integrated, can be suppressed. Accordingly, the largest possible compartment space can be secured in a fuel cell hybrid vehicle.

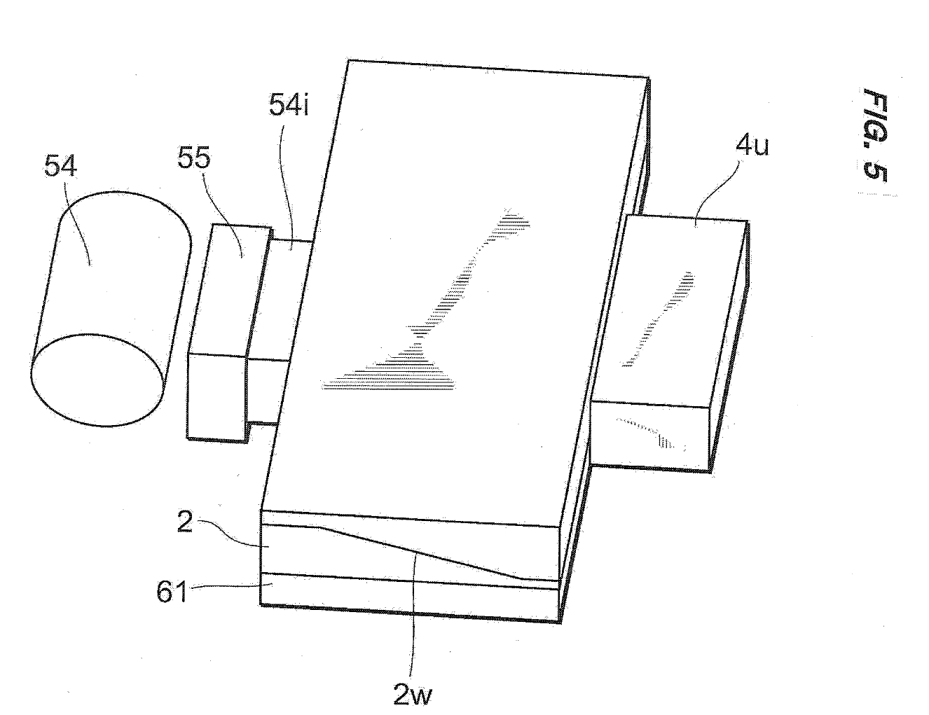

Although the above embodiment has described the configuration in which the FC converter 61 is arranged on the upper side of the fuel cell 2, the positional relationship between the FC converter 61 and the fuel cell 2 is not limited thereto. For example, the FC converter 61 may be arranged on the lower side of the fuel cell 2 as shown in FIG. 5. In this first modification, in the same way as in the above embodiment, the inverter 54i for the cooling-water pump 54, the ion exchanger 55 and the cooling-water pump 54, starting from the fuel cell 2 side, are arranged on the front side of the fuel cell 2, while a fuel-system non-power generating unit 4u is arranged on the rear side of the fuel cell 2. The fuel cell system in the first modification provides the same effects as the fuel cell system in the above embodiment.

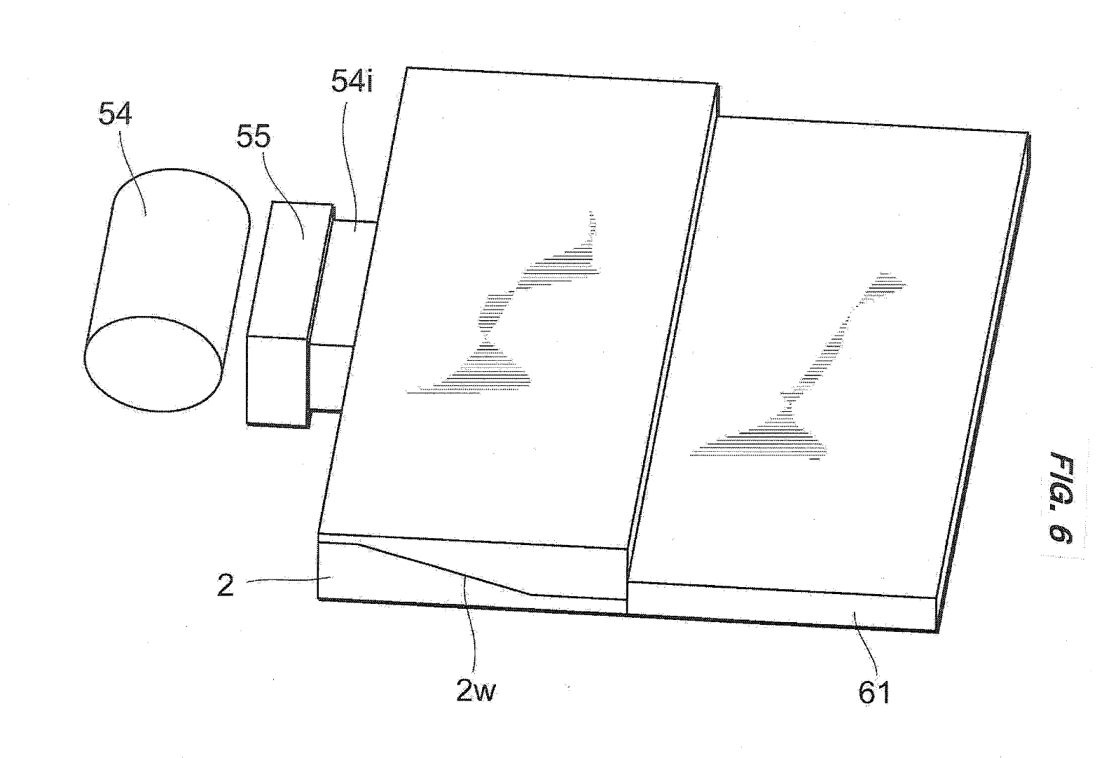

The FC converter 61 may be arranged on the rear side of the fuel cell 2 as shown in FIG. 6. In this second modification, in the same way as in the above embodiment, the inverter 54i for the cooling-water pump 54, the ion exchanger 55 and the cooling-water pump 54, starting from the fuel cell 2 side, are arranged on the front side of the fuel cell 2. However, in the second modification, since the FC converter 61 is arranged on the rear side of the fuel cell 2, the fuel-system non-power generating unit 4u is housed in a casing which houses the fuel cell 2.

Even if the fuel-system non-power generating unit 4u is housed in a casing which houses the fuel cell 2 as described above, since the FC converter 61 is arranged on the rear side of the fuel cell 2, the fuel cell 2 and the fuel-system non-power generating unit 4u can be arranged under a front seat of the vehicle without sacrificing the space of the passenger's compartment. In addition, although the FC converter 61 is to be arranged near the center floor part of the center tunnel in the vehicle, since the thickness of the FC converter 61 is minimized as described above, the FC converter 61 can be arranged without sacrificing the space of the center floor.

The configuration of the second modification is particularly effective when, for example, a space under the front seat is limited and thus it is difficult to arrange the fuel cell 2 and the FC converter 61 in a superposed state. If the fuel cell 2 and the FC converter 61 are arranged in the superposed state, as in the above embodiment and the first modification, the space for the FC converter 61 to be superposed needs to be secured under the front seat. However, if the space under a front seat is limited and thus the space for arranging the FC converter 61 and the fuel cell 2 cannot be secured, the performance of the fuel cell 2 would have to be lowered by, for example, reducing the output capacity of the fuel cell 2. In contrast, in the fuel cell system of the second modification, since only a space for arranging the fuel cell is required under the front seat, the fuel cell 2 can be installed without lowering the performance of the fuel cell 2.

In the protection frame in the second modification, the shape of the sub-frame unit 90b in the protection frame 90 shown in FIG. 4 preferably has the same shape as the shape of the main frame unit 90a. In such a configuration, the size of the main frame unit 90a is determined so as to match with the size of the fuel cell 2, and the size of the sub-frame unit 90b is determined so as to match with the size of the FC converter 61. With such a configuration, the FC converter 61 housed in the sub-frame unit can be protected from an impact resulting from contact with a road surface and can also be protected from an impact resulting from a vehicle crash from the lateral side.

Although the above-described embodiment and modifications have described the configuration in which the fuel cell system according to the present invention is applied to a fuel cell hybrid vehicle, the present invention is not limited thereto. The fuel cell system according to the present invention may be applied to various mobile objects (e.g., robots, ships and airplanes) in addition to the fuel cell hybrid vehicles. Furthermore, the fuel cell system according to the present invention may also be applied to stationary power generation systems used as power generating equipment for structures (e.g., houses and buildings).

### INDUSTRIAL APPLICABILITY

The fuel cell system according to the present invention is suitably used to secure the largest possible compartment space in which the fuel cell system is installed.

### DESCRIPTION OF REFERENCE NUMERALS

1: fuel cell system, 2: fuel cell, 2w: case joint portion, 3: oxidant gas pipe system, 4: fuel gas pipe system, 4u: fuel-system non-power generating unit, 45: gas-liquid separator, 46 exhaust/drain valve, 5: cooling system, 53: cooling-water circulation flow path, 54: cooling-water pump, 54i: inverter for cooling-water pump, 55: ion exchanger, 6: power system, 61: FC converter, 61a: reactor unit, 61b: voltage-increase control unit, 61c: condenser unit, 62: battery, 63: battery converter, 64: traction inverter, 65: traction motor, 7: control unit, 90: frame unit, 90a: main frame unit, 90b: sub-frame unit, 90w: lateral-side frame

1. A fuel cell system comprising:
a fuel cell; and
a voltage converter which increases an output voltage from the fuel cell and outputs the resulting output voltage to a power-consuming apparatus,
wherein a reactor unit, a voltage-increase control unit and a condenser unit included in the voltage converter are integrated so that the reactor unit, the voltage-increase control unit and the condenser unit do not superpose on each other in respective thickness directions thereof.

2. The fuel cell system according to claim 1, wherein the voltage converter is arranged on an upper side of the fuel cell with respect to the fuel cell which has been arranged.

3. The fuel cell system according to claim 1, wherein the voltage converter is arranged on a lower side of the fuel cell with respect to the fuel cell which has been arranged.

4. The fuel cell system according to claim 1, wherein the voltage converter is arranged on a rear side of the fuel cell with respect to the fuel cell which has been arranged.

5. The fuel cell system according to claim 1, further comprising:
a cooling-water circulation flow path which circulates and supplies cooling water to the fuel cell; and
a cooling-water pump which causes the cooling water to circulate in the cooling-water circulation flow path,
wherein the cooling-water pump is arranged on a front side of the fuel cell and the voltage converter with respect to the fuel cell and the voltage converter which have been arranged.

6. The fuel cell system according to claim 5, further comprising an ion exchanger which removes impurities contained in the cooling water,
wherein the ion exchanger is arranged on a front side of the fuel cell and the voltage converter with respect to the fuel cell and the voltage converter which have been arranged.

7. The fuel cell system according to claim 1, further comprising a protection member which protects the fuel cell,
wherein a part of the protection member is arranged so as to cross with a joint portion formed on the fuel cell, as seen from a lateral side of the fuel cell and the voltage converter which have been arranged.
